(19) United States
(12) Patent Application Publication
(10) Pub. No.: US 2019/0057647 A1
(43) Pub. Date: Feb. 21, 2019

(54) LOW LATENCY LOW VIDEO BANDWIDTH OLED DISPLAY ARCHITECTURE

(71) Applicant: Universal Display Corporation, Ewing, NJ (US)

(72) Inventor: Michael Hack, Ewing, NJ (US)

(21) Appl. No.: 16/044,868

(22) Filed: Jul. 25, 2018

Related U.S. Application Data
(60) Provisional application No. 62/547,182, filed on Aug. 18, 2017.

(51) Int. Cl. G09G 3/3225; H01L 27/32; G06F 3/01

(52) U.S. Cl. CPC G09G 3/3225; H01L 27/3213; G09G 2310/0264; H01L 27/3209; G06F 3/013

(57) ABSTRACT

An OLED display architecture includes an OLED display having a plurality of pixels, a video input source, and a data link having a data transfer rate, the data link being communicatively connected to the video input source and the OLED display, where a first subset of the pixels is updated at a first refresh rate and the remaining pixels are updated at a second refresh rate. A video display system and a method of driving a display are also disclosed.

### CROSS-REFERENCE TO RELATED APPLICATIONS

This application is a non-provisional of U.S. Provisional Patent Application Ser. No. 62/547,182, filed Aug. 18, 2017, the entire contents of which are incorporated herein by reference.

### FIELD

The present invention relates to architectures and methods for use with emissive displays and devices, such as organic light emitting diodes, including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

For VR applications, displays need to have very high resolution and low latency (high frame rate). For a conventional display architecture this requires very high data transfer rates between the video source and the display. OLED displays are particularly well-suited to VR implementations, because the individual display elements can be driven very quickly. OLEDs are not limited by slow liquid crystal response times. Where such high data rates cannot be achieved, due for example to hardware or software constraints, display resolution or frame rate is typically compromised. One way to reduce the required data rate is to only update parts of the display requiring low latency at a very high refresh rate, and update the remainder of the display at a lower refresh rate. This can lower the required video data rate, with no loss of visual clarity.

Thus, there is a need in the art for an improved OLED display architecture providing an increased framerate while limiting the required video data rate. The present invention satisfies that need.

### SUMMARY

According to one embodiment, an OLED display architecture includes an OLED display having a plurality of pixels; a video input source; and a data link having a data transfer rate, the data link being communicatively connected to the video input source and the OLED display; where a first subset of the pixels is updated at a first refresh rate and the remaining pixels are updated at a second refresh rate. In one embodiment, the OLED display architecture includes a display buffer comprising pixel data, communicatively connected to the OLED display, wherein the OLED display pixels are refreshed with the pixel data at the first refresh rate. In one embodiment, the OLED display architecture includes a controller configured to identify the first subset of pixels and transmit pixel data from the video input source corresponding to the first subset of pixels to the OLED display. In one embodiment, the OLED display architecture includes a motion detection module communicatively connected to the controller and to the video input source, wherein the controller is configured to designate a region of the video input source where there is fast motion as the first subset of pixels. In one embodiment, the OLED display architecture includes a controller and an eye tracking device configured to monitor the orientation of a subject's eye. In one embodiment, the first subset of pixels is selected based on the position of the subject's eye. In one embodiment, the first subset of pixels is selected to be within the subject's central viewing zone. In one embodiment, the first subset of pixels is selected based on a measurement of motion in the video input source. In one embodiment, the first refresh rate is different from the second refresh rate. In one embodiment, the first refresh rate is at least 5 times the second refresh rate. In one embodiment, the first refresh rate is at least 10 times the second refresh rate. In one embodiment, the data link transmits pixel data at an overall required data rate that is less than 50% of a data rate required for transmitting entire frames at the first refresh rate. In one embodiment, the overall required data rate is 40% of the data rate required for transmitting entire frames at the first refresh rate.

According to another embodiment, a video display system includes a display; a display video buffer communicatively connected to the display, configured to store a display video frame comprising display pixel data, the frame having a high update rate region and a low update rate region; a display controller communicatively connected to the display video buffer and a video input source; and a video data link configured to transmit pixel data from the video input source to the display video buffer; where the display controller is configured to update the pixel data in the high update rate region of the display video frame with the pixel data from the video input source at a first refresh rate; and where the display controller is configured to update the pixel data in the low update rate region of the display video frame with the pixel data from the video input source at a second refresh rate. In one embodiment, the high update rate region is selected based on the position of a subject's eye. In one embodiment, the video display system includes an eye monitoring sensor selected from the group consisting of an infrared sensor, an ultrasonic sensor, a camera, and an EM wave sensor. In one embodiment, the high update rate region is selected based on a measurement of motion in the video input source. In one embodiment, the video data includes the position of at least one region of the frame and pixel data for at least one region. In one embodiment, the first or second refresh rate is variable. In one embodiment, the first refresh rate is different from the second refresh rate. In one embodiment, the first refresh rate is at least 5 times the second refresh rate. In one embodiment, the first refresh rate is at least 10 times the second refresh rate. In one embodiment, the video data link transmits pixel data at an overall required data rate that is less than 50% of a data rate required for transmitting entire frames at the first refresh rate. In one embodiment, the overall required data rate is 40% of the data rate required for transmitting entire frames at the first refresh rate. In one embodiment, the video display is incorporated into a product selected from the group consisting of an OLED display, a LED display, a micro-LED display, an LCD display, a virtual reality display, an augmented reality display, an eyewear display, a headset display, a flat panel display, a computer monitor, a 3D display, a medical monitor, a television, a billboard, a heads up display, a fully transparent display, a flexible display, a laser printer, a telephone, a cell phone, a personal digital assistant, a laptop computer, a digital camera, a camcorder, a viewfinder, a micro-display, a vehicle, a large area wall, a theater or stadium screen, and a sign.

According to another embodiment, a video display system includes a display; a display video buffer communicatively connected to the display, configured to store a display video frame comprising display pixel data, the frame having a high update rate region and a low update rate region; an input video buffer communicatively connected to a video input source, configured to store an input video frame comprising input pixel data; a display controller communicatively connected to the display video buffer and the input video buffer; a video data link configured to transmit pixel data from the input video buffer to the display video buffer; where the display controller is configured to update the pixel data in the high update rate region of the display video frame with the pixel data from the input video frame at a first refresh rate; and where the display controller is configured to update the pixel data in the low update rate region of the display video frame with the pixel data from the input video frame at a second refresh rate. In one embodiment, the display comprises a single scan driver and a single data driver. In one embodiment, the high update rate region is selected based on the position of a subject's eye. In one embodiment, the video display system includes an eye monitoring sensor selected from the group consisting of an infrared sensor, an ultrasonic sensor, and an EM wave sensor. In one embodiment, the video display system includes a camera for tracking the eye movement of the subject. In one embodiment, the high update rate region is selected based on a measurement of motion in the video input source. In one embodiment, the video data includes the position of at least one region of the frame and pixel data for the at least one region. In one embodiment, the first refresh rate is variable. In one embodiment, the high update region comprises at least one entire row of pixel data, and the low update region comprises the remaining rows of pixel data. In one embodiment, the first refresh rate is at least 5 times the second refresh rate. In one embodiment, the video display is incorporated into a product selected from the group consisting of an OLED display, a LED display, a micro-LED and LCD display, a virtual reality display, an eyewear display, a headset display, a flat panel display, a computer monitor, a 3D display, a medical monitor, a television, a billboard, a heads up display, a fully transparent display, a flexible display, a laser printer, a telephone, a cell phone, a personal digital assistant, a laptop computer, a digital camera, a camcorder, a viewfinder, an augmented reality display, a micro-display, a vehicle, a large area wall, a theater or stadium screen, and a sign.

According to another embodiment, a method of driving a display includes the steps of storing an input video frame from a video input source in an input video buffer; dividing the input video frame into a high update rate region and a low update rate region, each region comprising pixel data; transmitting the high update rate region of the input video frame to a display video buffer containing a display video frame; updating the pixel data in the high update rate region of the display video frame with the pixel data of the transmitted input video frame; and driving the display with the updated pixel data. In one embodiment, the method includes the steps of detecting the orientation of a subject's eye with respect to the display; calculating a central viewing zone on the display of the subject's eye based on the detected orientation; and selecting as the high update rate region the calculated central viewing zone. In one embodiment, the orientation of the subject's eye is detected via a camera pointed at the subject's eye. In one embodiment, the method includes the steps of identifying a region of the input video frame wherein the video input source has high motion; and selecting as the high update rate region the region of the input video frame that has high motion. In one embodiment, the method includes the steps of transmitting the low update rate region of the input video frame to a display video buffer containing a display video frame; and updating the entire display video frame with the high update rate and low update rate regions of the transmitted input video frame. In one embodiment, the low update rate region of the input video frame is transmitted at most once for every five times the high update rate region. In one embodiment, the high update rate region is transmitted at a first framerate and the low update rate region is transmitted at a second framerate. In one embodiment, the first framerate is variable. In one embodiment, the high update region is defined as at least one entire row of pixel data, and the low update region comprises the remaining rows of pixel data.

According to another embodiment, an organic light emitting diode/device (OLED) is also provided. The OLED can include an anode, a cathode, and an organic layer, disposed between the anode and the cathode. According to yet another embodiment, the organic light emitting device is incorporated into one or more devices selected from a consumer product, an electronic component module, and/or a lighting panel.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an exemplary schematic of an OLED display architecture according to one embodiment.

FIG. 4 shows a flow chart of a method of driving a display according to one embodiment.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

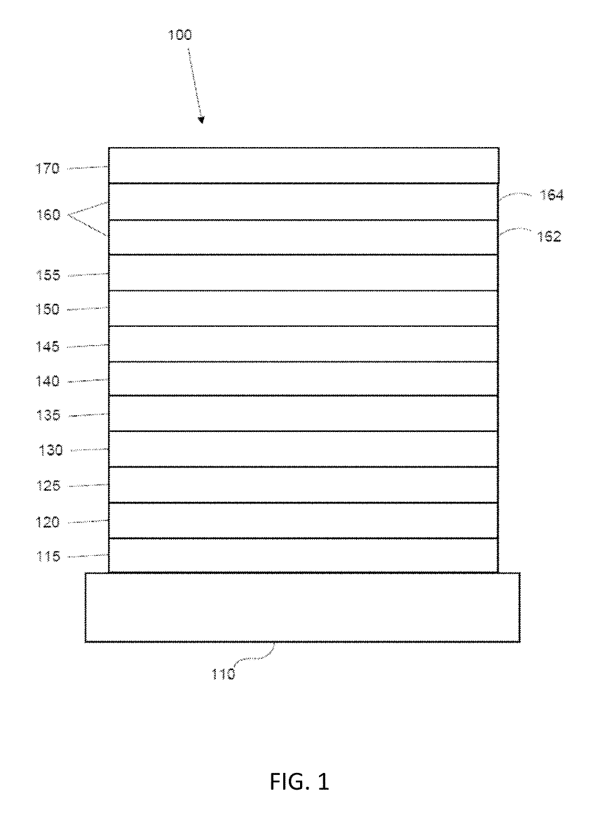

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

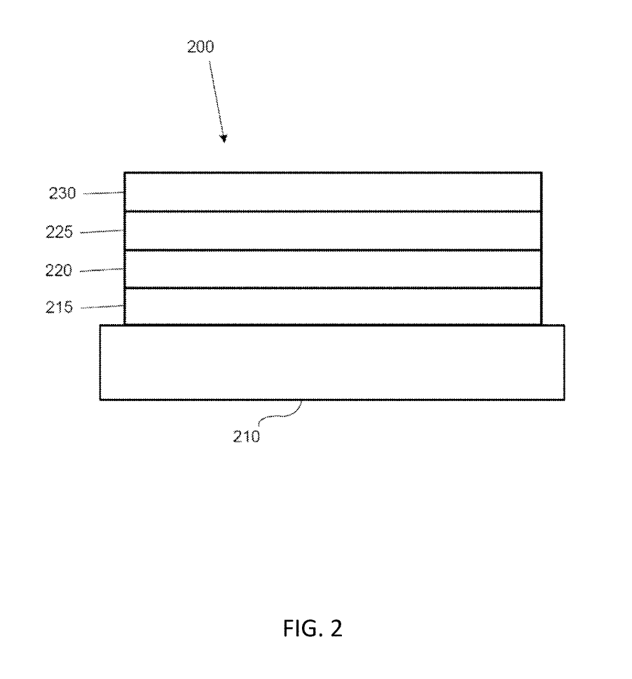

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material. EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

### Display Architecture

Devices and methods of the present invention generally relate to a display architecture for reducing the total data rate to a VR or other display without losing visual quality. In a typical, fixed-frame display, the total data rate is roughly the frame rate (in Hz) multiplied by the bits in a single frame. In an architecture of the present invention, the display is run at a high framerate, for example 85 Hz, 100 Hz, 120 Hz, 150 Hz, or 240 Hz, but the video information displayed is updated at different rates in different regions of the display, wherein the regions are selected based on one or more measured or computed factors. Examples of measured or computed factors include, but are not limited to, eye tracking and motion analysis. For example, on a display running at a 150 Hz framerate, video information displayed in a first region might be updated at full framerate of 150 Hz, but video information displayed in a second region might only be updated once every N frames. Suitable values of N include 2, 4, 5, 10, 20, or other values as dictated by the video source. In one embodiment, a first high refresh rate region is updated at 150 Hz, while a second low refresh rate region is updated at 30 Hz. In some embodiments, N has a constant value, but in other embodiments N varies over time. In some embodiments, the display is divided into more than two regions, and N can have different values in different regions of the display as needed. In some embodiments, the display may be divided into a first number of regions during a first time period, and may be divided into a second, different number of regions, each having a different fixed or variable value of N, during a second time period.

In an exemplary eye tracking embodiment, the display architecture incorporates one or more sensors for monitoring movement of the user's eye and defining a high update rate region of the display. Examples of suitable sensors include, but are not limited to, infrared sensors, ultrasonic sensors, cameras, and EM wave sensors. A controller of the present invention may then include a mapping module to translate the measured eye position into one or more regions in a displayed frame. The region at which the user is looking can then be updated at a higher rate (giving it a higher effective framerate) than the rest of the display that is outside the user's central field of view. In one embodiment, the eye tracking method requires user to wear some special sensors, such as infrared sensors or reflectors, ultra-sonic wave receivers, and electromagnetic wave sensors. Video-based methods can track users in a passive manner. In general, a camera is can used to observe a user and track eye movement according to various methods known in the art. Image features of the user can be extracted and can help to track the motion of the user's head. The graphics systems can then be con-trolled according to the tracking results.

In an exemplary motion analysis embodiment, the source video data is analyzed for regions having high motion and defining a high update rate region of the display. In some embodiments, this analysis is performed in real time. In other embodiments, the analysis is performed in advance on some or all of the video data. Where one region of source video data displays faster motion than another region of video data, the fast motion region can be updated at a higher frame rate than the surrounding regions. Image processing can be applied to the video images to look for objects that move substantially relative to their size from one video frame to the next.

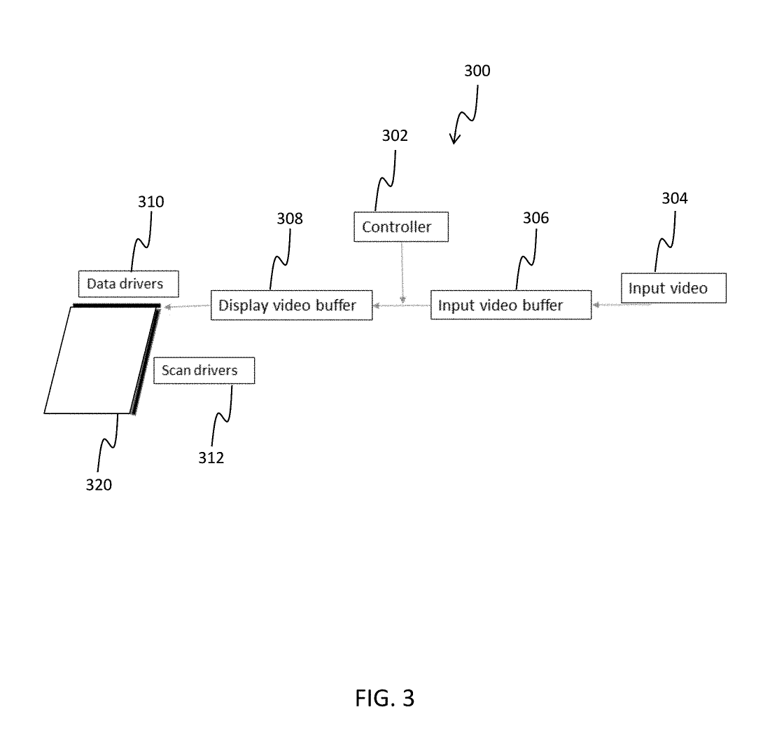

With reference now to FIG. 3, a schematic of an OLED display architecture 300 is shown according to one embodiment. Data is supplied to a display 320 having one or more data drivers 310 and one or more scan drivers 312. The video input data format can include one shift register running at high speed to support a high frame rate. The data is supplied to the display 320 at high speed and at high frame rate from the display buffer 308, but less than 100% of scan lines are refreshed with data updated at the high frame rate. The remainder of the scan lines are refreshed at only a low frame rate, so the same video information will be fed to these pixels for N frames. This reduces overall data rates. In some embodiments, the frame data updated at a higher rate is defined not only as a subset of full scan lines (rows) but as one or more pixel regions on the display. The one or more pixel regions may each comprise one or more individual pixels, and may be defined as comprising one or more scan lines, one or more data lines, or as arbitrarily-shaped regions of the display. The architecture in one embodiment uses two frame buffers. A display video buffer 308 supports the immediate transfer of video image to the display 320, and the pixel data contained therein is in one embodiment completely transmitted to the display 320 once every high speed frame rate. A second frame buffer—the input video buffer 306—is fed from an input video module 304 and updates the display buffer 308 with logic manipulation. Pixel data contained within the display video buffer 308 designated as high frame rate receives real time video information updated from the input video buffer 306. For example, if slow update rate pixel data regions are updated at one fifth (1/N) the rate of the high frame rate pixel data regions, then only one fifth of the slow frame rate scan lines will be updated each time the input video receives a new video frame. This process is implemented by the controller 302. In some embodiments, input video pixel data from the input video source 304 includes information about which pixel data regions are low refresh rate and which are high refresh rate. Pixel data corresponding to the low update rate regions will only be updated (i.e. transmitted from the input video buffer 306 to the display video buffer 308) every N frames, where N=the ratio of high to low frame rate (e.g. 5:1), unless they are otherwise designated as high update rate regions. Pixel data in high update rate regions are updated every high frame rate.

In some embodiments, boundaries between high update rate regions and low update rate regions are updated at a gradient frame rate, that is, instead of one pixel being updated once every ten frames and its neighboring pixel being updated once every frame, a border region may be defined between the high and low update rate regions wherein the pixels in the border region are updated once every five frames. In other embodiments, the border region may itself be divided into multiple pixel update rate regions, wherein some pixels in the border region are updated once every seven frames, and some pixels in the border region are updated once every three frames. In such embodiments, any contrast between the high update rate regions and the low update rate regions may be eased by gradually increasing the frame rate as the display approaches the high update rate region.

In one embodiment, video data from first input buffer is transferred to the display buffer in a process controlled by the display controller. The controller feeds high refresh rate data such that scan line data is refreshed every frame rate. 1/N of remaining scan lines will be refreshed every frame rate, with the controller enabling this process. In some embodiments, the controller feeds high refresh rate data into the display video buffer such that high refresh rate pixel data is updated every frame rate, and feeds low refresh rate data less frequently, such that the low refresh rate pixel data is updated once every N frames. In some embodiments, where 1/N is the lowest refresh rate (in Hz), the input video buffer transmits an entire frame of pixel data to the display video buffer once every N frames. In one embodiment, the maximum permissible video data rate transfer to the display, relative to the bandwidth requirements of the data rate assuming all pixels are refreshed at high frame rate, will determine either the maximum % of scan lines that can be viewed as high refresh rate, or else if a higher % is needed, then the whole display frame rate will have to be slowed down accordingly. In one embodiment, the system may require eye tracking to determine which rows or pixel regions are to be designated as high frame rate, based on those at the center of the eye's field of vision, or those rows or pixel regions in which the pixel data indicates that objects are moving or changing at high speed.

Data rate savings provide a significant advantage over conventional architectures. In one example, let X=high speed data rate based on high frame rate and total number of pixels. Assume 25% of pixels are required to be high frame rate, and 75% low frame rate (based on motion within the image or where eye is positioned). If the low frame rate is 20% of the high frame rate (for example, 30 Hz compared to 150 Hz), then N=5. The overall required data rate=0.25X+0.75 (X/5)=0.4X, thus, only requiring 40% of the previous data rate for the same visual quality.

In one embodiment, an OLED display shows full motion video where the refresh rate of each pixel depends on a system determined refresh rate dependent on reducing motion latency. In one embodiment, the individual pixel refresh rate is dependent on whether or not a pixel is in the central viewing zone of a viewer's eye. In one aspect, individual pixel refresh rates are dependent on whether the video at that pixel is rendering fast motion. In one embodiment, display frame rates support pixel updating with low visual latency. In one aspect, the input video data rate is less than that required to update each pixel at the display frame rate. In one embodiment, video processing circuits contain 2 or more buffers. In one embodiment, pixels in a central viewing zone or that are rendering fast motion are refreshed every frame rate. In one embodiment, pixels not in a central viewing zone or not rendering fast motion are refreshed every N frames. In one embodiment, the controller controls which pixels are updated every frame rate and which are updated every N frames.

In one embodiment, the OLED display architecture includes an OLED display having a plurality of pixels, a video input source, and a data link having a data transfer rate. The data link is communicatively connected to the video input source and the OLED display. In one embodiment, a first subset of the pixels is updated at a first refresh rate and the remaining pixels are updated at a second refresh rate. In one embodiment, the OLED display architecture includes a display buffer having pixel data, communicatively connected to the OLED display. The OLED display pixels are refreshed with the pixel data at the first refresh rate. In one embodiment, the OLED display architecture includes a controller that identifies the first subset of pixels and transmit pixel data from the video input source corresponding to the first subset of pixels to the OLED display. In one embodiment, the OLED display architecture includes a motion detection module communicatively connected to the controller and to the video input source. The controller can be configured to designate a region of the video input source where there is fast motion as the first subset of pixels. In one embodiment, the OLED display architecture includes a controller and an eye tracking device configured to monitor the orientation of a subject's eye. In one embodiment, the first subset of pixels is selected based on the position of the subject's eye. In one embodiment, the first subset of pixels is selected to be within the subject's central viewing zone. In one embodiment, the first subset of pixels is selected based on a measurement of motion in the video input source. In one embodiment, the first refresh rate is different from the second refresh rate. In one embodiment, the first refresh rate is at least 5 times the second refresh rate. In one embodiment, the first refresh rate is at least 10 times the second refresh rate. In one embodiment, the data link transmits pixel data at an overall required data rate that is less than 50% of a data rate required for transmitting entire frames at the first refresh rate. In one embodiment, the overall required data rate is 40% of the data rate required for transmitting entire frames at the first refresh rate.

In one embodiment, a video display system includes a display, a display video buffer communicatively connected to the display. It can be configured to store a display video frame comprising display pixel data, the frame having a high update rate region and a low update rate region. A display controller is connected to the display video buffer and a video input source. A video data link is configured to transmit pixel data from the video input source to the display video buffer. The display controller is configured to update the pixel data in the high update rate region of the display video frame with the pixel data from the video input source at a first refresh rate. The display controller is configured to update the pixel data in the low update rate region of the display video frame with the pixel data from the video input source at a second refresh rate. In one embodiment, the high update rate region is selected based on the position of a subject's eye. In one embodiment, the video display system includes an eye monitoring sensor selected from the group consisting of an infrared sensor, an ultrasonic sensor, a camera, and an EM wave sensor. In one embodiment, the high update rate region is selected based on a measurement of motion in the video input source. In one embodiment, the video data includes the position of at least one region of the frame and pixel data for at least one region. In one embodiment, the first or second refresh rate is variable. In one embodiment, the first refresh rate is different from the second refresh rate. In one embodiment, the first refresh rate is at least 5 times the second refresh rate. In one embodiment, the first refresh rate is at least 10 times the second refresh rate. In one embodiment, the video data link transmits pixel data at an overall required data rate that is less than 50% of a data rate required for transmitting entire frames at the first refresh rate. In one embodiment, the overall required data rate is 40% of the data rate required for transmitting entire frames at the first refresh rate. In one embodiment, the video display is incorporated into a product selected from the group consisting of an OLED display, a LED display, a micro-LED display, an LCD display, a virtual reality display, an augmented reality display, an eyewear display, a headset display, a flat panel display, a computer monitor, a 3D display, a medical monitor, a television, a billboard, a heads up display, a fully transparent display, a flexible display, a laser printer, a telephone, a cell phone, a personal digital assistant, a laptop computer, a digital camera, a camcorder, a viewfinder, a micro-display, a vehicle, a large area wall, a theater or stadium screen, and a sign.

In one embodiment, a video display system includes a display, a display video buffer communicatively connected to the display, configured to store a display video frame comprising display pixel data, the frame having a high update rate region and a low update rate region, an input video buffer communicatively connected to a video input source, configured to store an input video frame comprising input pixel data, a display controller communicatively connected to the display video buffer and the input video buffer, and a video data link configured to transmit pixel data from the input video buffer to the display video buffer. The display controller is configured to update the pixel data in the high update rate region of the display video frame with the pixel data from the input video frame at a first refresh rate. The display controller is configured to update the pixel data in the low update rate region of the display video frame with the pixel data from the input video frame at a second refresh rate. In one embodiment, the display includes a single scan driver and a single data driver. In one embodiment, the high update rate region is selected based on the position of a subject's eye. In one embodiment, the video display system includes an eye monitoring sensor selected from the group consisting of an infrared sensor, an ultrasonic sensor, and an EM wave sensor. In one embodiment, the video display system includes a camera for tracking the eye movement of the subject. In one embodiment, the high update rate region is selected based on a measurement of motion in the video input source. In one embodiment, the video data includes the position of at least one region of the frame and pixel data for the at least one region. In one embodiment, the first refresh rate is variable. In one embodiment, the high update region comprises at least one entire row of pixel data, and the low update region comprises the remaining rows of pixel data. In one embodiment, the first refresh rate is at least 5 times the second refresh rate. In one embodiment, the video display is incorporated into a product selected from the group consisting of an OLED display, a LED display, a micro-LED and LCD display, a virtual reality display, an eyewear display, a headset display, a flat panel display, a computer monitor, a 3D display, a medical monitor, a television, a billboard, a heads up display, a fully transparent display, a flexible display, a laser printer, a telephone, a cell phone, a personal digital assistant, a laptop computer, a digital camera, a camcorder, a viewfinder, an augmented reality display, a micro-display, a vehicle, a large area wall, a theater or stadium screen, and a sign.

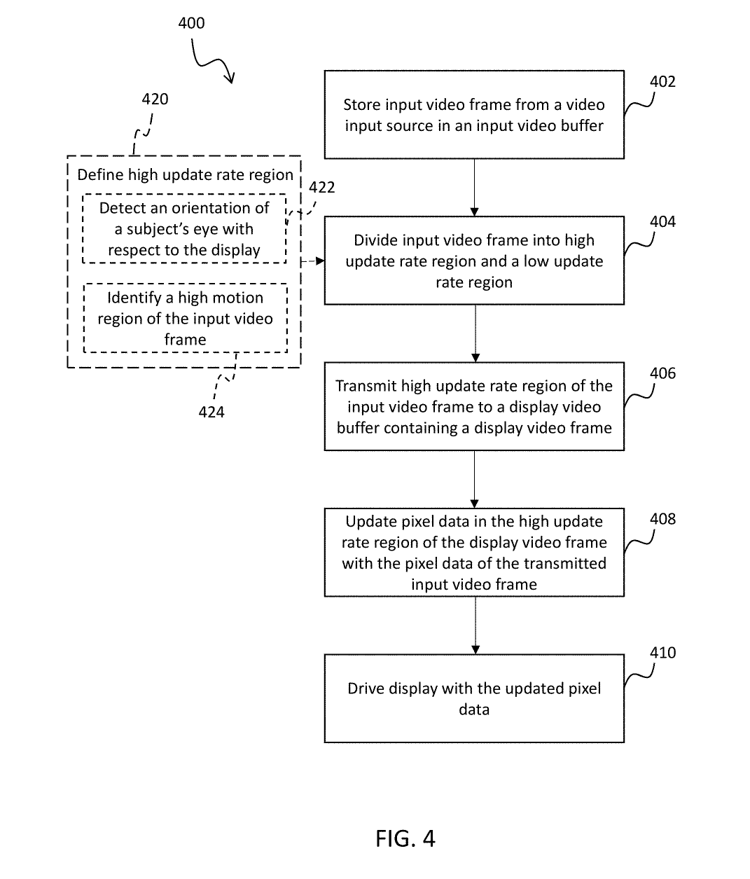

With reference now to FIG. 4, a method 400 of driving a display is shown according to one embodiment. An input video frame from a video input source is stored in an input video buffer 402. The input video frame is divided into a high update rate region and a low update rate region, each region comprising pixel data 404. The high update rate region can be defined 420 using various techniques, including but not limited to detecting an orientation of a subject's eye with respect to the display 422, or identifying a high motion region of the input video frame 424. Next, the high update rate region of the input video frame is transmitted to a display video buffer containing a display video frame 406. The pixel data is updated in the high update rate region of the display video frame with the pixel data of the transmitted input video frame 408. Finally, the display is driven with the updated pixel data 410. In one embodiment, the method includes the steps of detecting the orientation of a subject's eye with respect to the display; calculating a central viewing zone on the display of the subject's eye based on the detected orientation; and selecting as the high update rate region the calculated central viewing zone. In one embodiment, the orientation of the subject's eye is detected via a camera pointed at the subject's eye. In one embodiment, the method includes the steps of identifying a region of the input video frame wherein the video input source has high motion; and selecting as the high update rate region the region of the input video frame that has high motion. In one embodiment, the method includes the steps of transmitting the low update rate region of the input video frame to a display video buffer containing a display video frame; and updating the entire display video frame with the high update rate and low update rate regions of the transmitted input video frame. In one embodiment, the low update rate region of the input video frame is transmitted at most once for every five times the high update rate region. In one embodiment, the high update rate region is transmitted at a first framerate and the low update rate region is transmitted at a second framerate. In one embodiment, the first framerate is variable. In one embodiment, the high update region is defined as at least one entire row of pixel data, and the low update region comprises the remaining rows of pixel data.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An OLED display architecture, comprising:
an OLED display having a plurality of pixels;
a video input source; and
a data link having a data transfer rate, the data link being communicatively connected to the video input source and the OLED display;
wherein a first subset of the pixels is updated at a first refresh rate and the remaining pixels are updated at a second refresh rate.

2. The OLED display architecture of claim 1, further comprising a display buffer comprising pixel data, communicatively connected to the OLED display, wherein the OLED display pixels are refreshed with the pixel data at the first refresh rate.

3. The OLED display architecture of claim 1, further comprising a controller configured to identify the first subset of pixels and transmit pixel data from the video input source corresponding to the first subset of pixels to the OLED display.

4. The OLED display architecture of claim 3, further comprising a motion detection module communicatively connected to the controller and to the video input source, wherein the controller is configured to designate a region of the video input source where there is fast motion as the first subset of pixels.

5. The OLED display architecture of claim 3, further comprising a controller and an eye tracking device configured to monitor the orientation of a subject's eye.

6. The OLED display architecture of claim 5, wherein the first subset of pixels is selected based on the position of the subject's eye.

7. The OLED display architecture of claim 5, wherein the first subset of pixels is selected to be within the subject's central viewing zone.

8-13. (canceled)

14. A video display system, comprising:
a display;
a display video buffer communicatively connected to the display, configured to store a display video frame comprising display pixel data, the frame having a high update rate region and a low update rate region;
a display controller communicatively connected to the display video buffer and a video input source; and
a video data link configured to transmit pixel data from the video input source to the display video buffer;
wherein the display controller is configured to update the pixel data in the high update rate region of the display video frame with the pixel data from the video input source at a first refresh rate; and
wherein the display controller is configured to update the pixel data in the low update rate region of the display video frame with the pixel data from the video input source at a second refresh rate.

15. The video display system of claim 14, wherein the high update rate region is selected based on the position of a subject's eye.

16. (canceled)

17. The video display system of claim 14, wherein the high update rate region is selected based on a measurement of motion in the video input source.

18-24. (canceled)

25. The video display system of claim 14, wherein the video display is incorporated into a product selected from the group consisting of an OLED display, a LED display, a micro-LED display, an LCD display, a virtual reality display, an augmented reality display, an eyewear display, a headset display, a flat panel display, a computer monitor, a 3D display, a medical monitor, a television, a billboard, a heads up display, a fully transparent display, a flexible display, a laser printer, a telephone, a cell phone, a personal digital assistant, a laptop computer, a digital camera, a camcorder, a viewfinder, a micro-display, a vehicle, a large area wall, a theater or stadium screen, and a sign.

26-36. (canceled)

37. A method of driving a display, comprising the steps of:
storing an input video frame from a video input source in an input video buffer;
dividing the input video frame into a high update rate region and a low update rate region, each region comprising pixel data;
transmitting the high update rate region of the input video frame to a display video buffer containing a display video frame;
updating the pixel data in the high update rate region of the display video frame with the pixel data of the transmitted input video frame; and
driving the display with the updated pixel data.

38. The method of claim 37, further comprising the steps of:
detecting the orientation of a subject's eye with respect to the display;
calculating a central viewing zone on the display of the subject's eye based on the detected orientation; and
selecting as the high update rate region the calculated central viewing zone.

39. The method of claim 38, wherein the orientation of the subject's eye is detected via a camera pointed at the subject's eye.

40. The method of claim 37, further comprising the steps of:
identifying a region of the input video frame wherein the video input source has high motion; and
selecting as the high update rate region the region of the input video frame that has high motion.

41. The method of claim 37, further comprising the steps of:
transmitting the low update rate region of the input video frame to a display video buffer containing a display video frame; and
updating the entire display video frame with the high update rate and low update rate regions of the transmitted input video frame.

42. The method of claim 41, wherein the low update rate region of the input video frame is transmitted at most once for every five times the high update rate region.

43. The method of claim 41, wherein the high update rate region is transmitted at a first framerate and the low update rate region is transmitted at a second framerate.

44. The method of claim 43, wherein the first framerate is variable.

45. The method of claim 37, wherein the high update region is defined as at least one entire row of pixel data, and the low update region comprises the remaining rows of pixel data.
